(19) United States
(12) Patent Application Publication
(10) Pub. No.: US 2017/0077341 A1
(43) Pub. Date: Mar. 16, 2017

(54) SOLAR CELL

(71) Applicant: Solar Frontier K.K., Tokyo (JP)

(72) Inventors: Hiroki SUGIMOTO, Tokyo (JP); Takuya KATOU, Tokyo (JP); Noriyuki SAKAI, Tokyo (JP)

(73) Assignee: Solar Frontier K.K., Tokyo (JP)

(21) Appl. No.: 15/308,906

(22) PCT Filed: Apr. 23, 2015
(86) PCT No.: PCT/JP2015/062430

§ 371 Date: Nov. 4, 2016

(30) Foreign Application Priority Data
May 22, 2014 (JP) 2014-105964

(51) Int. Cl. H01L 31/0749

(52) U.S. Cl. CPC H01L 31/0749

(57) ABSTRACT

This solar cell is provided with a substrate (11), a first electrode layer (12) which is arranged on the substrate (11), a p-type CZTS light absorption layer (13) which is arranged on the first electrode layer (12) and which contains copper, zinc, tin, and group VI elements including sulfur and selenium, and an n-type second electrode layer (15) which is arranged on the CZTS light absorption layer (13), wherein the sulfur concentration in the group VI elements in the CZTS light absorption layer (13) increases, in the depth direction, from the side facing the second electrode layer (15) towards the side facing the first electrode layer (12).

### TECHNICAL FIELD

The present invention relates to a solar cell.

### BACKGROUND ART

A thin-film solar cell using a I₂-(II-IV)-VI₄ group compound semiconductor in a p-type light absorption layer has recently attracted attention. A thin-film solar cell using a chalcogenide-based I₂-(II-IV)-VI₄ group compound semiconductor including Cu, Zn, Sn, S or Se in a p-type light absorption layer is called a CZTS-based thin-film solar cell. Representative p-type light absorption layers include Cu₂ZnSnSe₄ and Cu₂ZnSn(S,Se)₄.

The CZTS-based thin-film solar cell is produced with relatively inexpensive and easily available materials, is relatively easy in production method thereof and also has a high absorption coefficient in the range from visible to near-infrared wavelengths, and therefore is expected to be high in photoelectric conversion efficiency and is thus believed to be a promising candidate for next generation solar cells.

The CZTS-based thin-film solar cell is produced by forming a metal back electrode layer on a substrate, forming a p-type CZTS-based light absorption layer thereon, and further sequentially stacking an n-type high-resistance buffer layer and an n-type transparent conductive film. A metal high in corrosion resistance and high in melting point, such as molybdenum (Mo), titanium (Ti) or chromium (Cr), is used for the material of the metal back electrode layer. The p-type CZTS-based light absorption layer is produced by, for example, forming a precursor film of Cu—Zn—Sn or Cu—Zn—Sn—Se—S on a substrate with a metal back electrode layer of molybdenum (Mo) or the like formed thereon, by a sputtering method or the like, and the resultant is subjected to sulfurization or selenization in a hydrogen sulfide or hydrogen selenide atmosphere.

### CITATIONS LIST

### Patent Literature

Patent literature 1: Japanese Laid-open Patent Publication No. 2012-160556

Patent literature 2: Japanese Laid-open Patent Publication No. 2012-253239

### SUMMARY OF INVENTION

### Technical Problem

While the CZTS-based thin-film solar cell is high in potentiality, the photoelectric conversion efficiency thereof currently realized is lower than a theoretical value, and the production technique thereof is demanded to further progress.

The present invention has been made in view of such circumstances, and an object thereof is to provide a solar cell including a CZTS-based light absorption layer having a higher photoelectric conversion efficiency.

### Solution to Problem

The solar cell disclosed in the present invention includes a substrate, a first electrode layer disposed on the substrate, a p-type CZTS-based light absorption layer disposed on the first electrode layer and having copper, zinc and tin, and a VI group element including sulfur and selenium, and an n-type second electrode layer disposed on the CZTS-based light absorption layer, in which the sulfur concentration in the VI group element in the depth direction of the CZTS-based light absorption layer is increased from the second electrode layer side towards the first electrode layer side.

### Advantageous Effects of Invention

The solar cell disclosed in the present specification has a high photoelectric conversion efficiency.

### BRIEF DESCRIPTION OF DRAWINGS

FIG. 1 is a view illustrating one embodiment of a solar cell disclosed in the present specification.

FIG. 2 is a graph illustrating the band structure of a solar cell including a conventional CIS-based light absorption layer.

FIG. 3 is a graph illustrating the band structure of the solar cell disclosed in the present specification.

FIG. 4A is a view (Part 1) illustrating a first embodiment of a method for producing the solar cell disclosed in the present specification.

FIG. 4B is a view (Part 2) illustrating the first embodiment of the method for producing the solar cell disclosed in the present specification.

FIG. 4C is a view (Part 3) illustrating the first embodiment of the method for producing the solar cell disclosed in the present specification.

FIG. 5D is a view (Part 4) illustrating the first embodiment of the method for producing the solar cell disclosed in the present specification,

FIG. 5E is a view (Part 5) illustrating the first embodiment of the method for producing the solar cell disclosed in the present specification.

FIG. 6 is a diagram illustrating production conditions of the first embodiment of the method for producing the solar cell disclosed in the present specification.

FIG. 7A is a view (Part 1) illustrating a second embodiment of the method for producing the solar cell disclosed in the present specification.

FIG. 7B is a view (Part 2) illustrating the second embodiment of the method for producing the solar cell disclosed in the present specification.

FIG. 7C is a view (Part 3) illustrating the second embodiment of the method for producing the solar cell disclosed in the present specification.

FIG. 8D is a view (Part 4) illustrating the second embodiment of the method for producing the solar cell disclosed in the present specification.

FIG. 8E is a view (Part 5) illustrating the second embodiment of the method for producing the solar cell disclosed in the present specification.

FIG. 8F is a view (Part 6) illustrating the second embodiment of the method for producing the solar cell disclosed in the present specification.

FIG. 9 is a diagram illustrating production conditions of the second embodiment of the method for producing the solar cell disclosed in the present specification.

FIG. 10 is a diagram describing the evaluation results in Experimental Example 1 and Experimental Example 2, and Comparative Experimental Example disclosed in the present specification.

FIG. 11A is a graph illustrating the distribution in the depth direction of the atomic ratio of sulfur to the VI group element in Experimental Example 1 disclosed in the present specification.

FIG. 11B is a graph illustrating the distribution in the depth direction of the atomic ratio of sulfur to the VI group element in Experimental Example 2 disclosed in the present specification.

FIG. 11C is a graph illustrating the distribution in the depth direction of the atomic ratio of sulfur to the VI group element in Comparative Experimental Example disclosed in the present specification.

### DESCRIPTION OF EMBODIMENTS

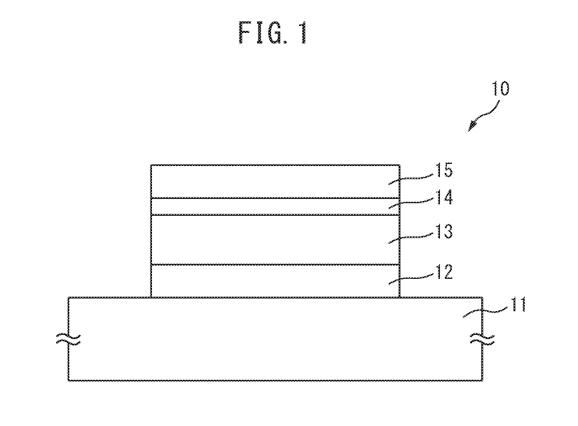

FIG. 1 is a view illustrating the cross-sectional structure of a solar cell disclosed in the present specification.

A solar cell 10 includes a substrate 11, a first electrode layer 12 disposed on the substrate 11, a CZTS-based light absorption layer 13 disposed on the first electrode layer 12 and having p-type conductivity, a buffer layer 14 disposed on the CZTS-based light absorption layer 13, exhibiting n-type conductivity and having a high resistance, and a transparent second electrode layer 15 disposed on the buffer layer 14 and having n-type conductivity.

For example, a glass substrate such as soda lime glass or low alkaline glass, a metal substrate such as a stainless plate, or a polyimide resin substrate can be used as the substrate 11.

For example, a metal conductive layer whose material is a metal such as Mo, Cr or Ti can be used as the first electrode layer 12.

The CZTS-based light absorption layer 13 is formed with, for example, a I₂-(II-IV)-VI₄ group compound semiconductor. For example, copper (Cu) can be used as the I group element. For example, zinc (Zn) can be used as the II group element. For example, tin (Sn) can be used as the IV group element. For example, sulfur (5) or selenium (Se) can be used as the VI group element. Specifically, the CZTS-based light absorption layer 13 includes a mixed crystal (Cu₂ZnSn(Se,S)₄) of Cu₂ (Zn, Sn)Se₄ and Cu₂(Zn,Sn)S₄. The compositional ratio of the I group element, the II-IV group element and the VI group element in the I₂-(II-IV)-VI₄ compound semiconductor may not be critically 1:1:2. In addition, the ratio of the II group element to the IV group element may not be critically 1:1. In addition, the compound semiconductor may include an element other than Cu, as the I group element. The compound semiconductor may include an element other than Zn, as the II group element. The compound semiconductor may include an element other than Sn, as the IV group element. The compound semiconductor may include an element other than S and Se, as the IV group element.

The n-type buffer layer 14 having a high resistance is, for example, a thin film (film thickness: about 3 nm to 50 nm) of a compound including Cd, Zn and/or In, and is representatively formed from CdS, ZnO, ZnS, Zn(OH)₂ or a mixed crystal thereof: Zn(O, S, OH); and/or InS, InO, In(OH) or a mixed crystal thereof: In(O, S, OH). While the layer is generally formed by a chemical bath deposition (CBD method), a metal organic chemical vapor deposition (MOCVD method) or an atomic layer deposition method (ALP method) can also be utilized as a dry process. The CBD method refers to a method where a base material is immersed in a solution including chemical species serving as a precursor and a heterogeneous reaction is allowed to progress between the solution and the surface of the base material to deposit a thin film on the base material.

The second electrode layer 15 is formed from a material having n-type conductivity, and being wide in forbidden band width, transparent and low in resistance. Specifically, the second electrode layer 15 includes a zinc oxide-based thin film (ZnO) or an ITO thin film. When the ZnO film is adopted, a III group element (for example, Al, Ga or B) can be added as a dopant to result in a reduction in resistivity. The second electrode layer 15 can also be formed by a sputtering method (DC, RF) or the like, besides the MOCVD method.

The present inventors have made studies about a further enhancement in the photoelectric conversion efficiency of the solar cell including the CZTS-based light absorption layer.

For example, a CIS-based thin-film solar cell where a I-III-VI₂ group compound semiconductor is used in a light absorption layer is known as a compound-based thin-film solar cell where a compound-based semiconductor is used in a light absorption layer, as in the CZTS-based thin-film solar cell.

In the CIS-based thin-film solar cell, a rare metal such as in or Ga is used as the III group element included in the light absorption layer. On the other hand, in the CZTS-based thin-film solar cell, Cu, Zn, Sn and the VI group element which are relatively inexpensive and easily available are used in the light absorption layer.

The CIS-based thin-film solar cell has the same structure as that of the CZTS-based thin-film solar cell illustrated in FIG. 1 except that the materials forming the light absorption layer are different.

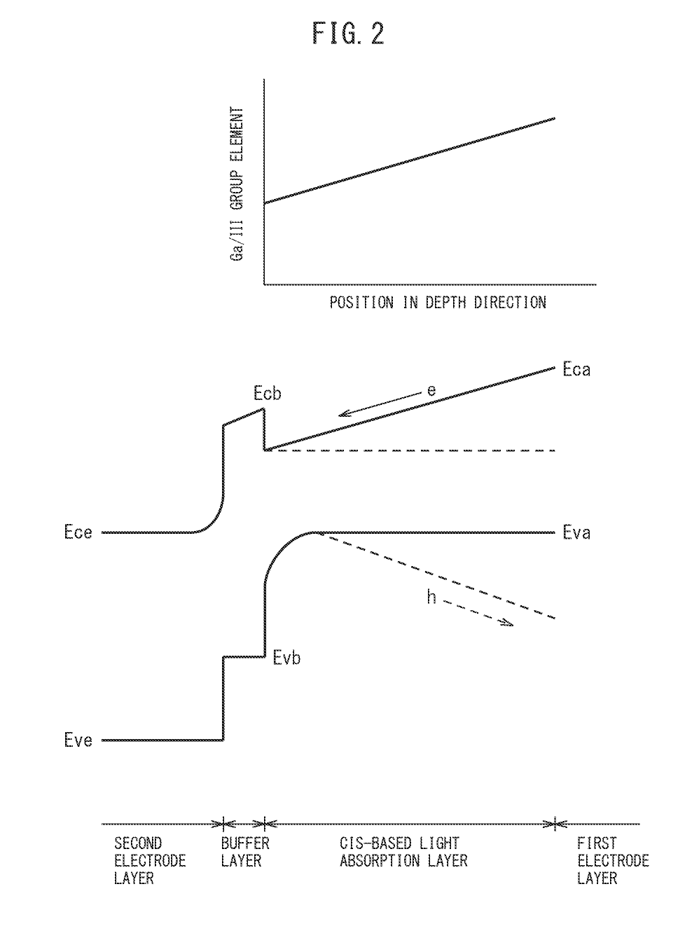

As illustrated in FIG. 2, the following is proposed with respect to the CIS-based thin-film solar cell: the Ga concentration in the III group element in the depth direction of a CIS-based light absorption layer is distributed so as to be increased from a buffer layer side towards a first electrode layer side, and the energy level at the lower end of the conduction band of the CIS-based light absorption layer thereby has a gradient in such a manner as to increase from the buffer layer side towards the first electrode layer side, resulting in an enhancement in photoelectric conversion efficiency.

In the graph in FIG. 2, the vertical axis represents the atomic ratio of Ga to the III group element in the CIS-based light absorption layer, and the horizontal axis represents the position in the depth direction of the CIS-based light absorption layer, from the interface of the buffer layer.

As illustrated in FIG. 2, the energy level at the lower end of the conduction band of the CIS-based light absorption layer is increased along with an increase in the Ga concentration in the III group element. An electron that absorbs light energy to transit to the lower end of the conduction band is moved to a position where the potential energy is lower, and therefore the electron is promoted to be moved to the buffer layer to result in an increase in photoelectric conversion efficiency.

The CZTS-based light absorption layer; however, does not include any III group element such as Ga, and therefore the procedure for an increase in photoelectric conversion efficiency of the CIS-based thin-film solar cell may not be applied to the CZTS-based thin-film solar cell.

in addition, the CIS-based light absorption layer includes a VI group element such as S as in the CZTS-based light absorption layer. It is then known that the sulfur concentration in the VI group element in the depth direction of the CIS-based light absorption layer is distributed so as to be increased from the second electrode layer side towards the first electrode layer side, to result in a decrease in the energy level at the upper end of the valance band from the buffer layer side towards the first electrode layer side without any change in the energy level at the lower end of the conduction band of the CIS-based light absorption layer, as indicated by the chain line in FIG. 2. Accordingly, the photoelectric conversion efficiency is not enhanced even by an increase in the S concentration in the VI group element in the CIS-based light absorption layer.

On the contrary, the present inventors have found that the sulfur concentration in the VI group element in the CZTS-based light absorption layer is increased to result in an increase in the energy level at the lower end of the conduction band without any change in the energy level at the upper end of the valance band of the CZTS-based light absorption layer.

The present inventors have achieved the following result: when a plurality of samples in which the sulfur concentration in the VI group element in the CZTS-based light absorption layer is changed are prepared and the band structure of each of the samples is measured by inverse photoemission spectroscopy, the energy level at the lower end of the conduction band is increased along with an increase in the sulfur concentration in the VI group element.

The present inventors have thus found that the relationship between the sulfur concentration in the VI group element in the light absorption layer and the band structure in the CZTS-based light absorption layer is different from that in the CIS-based light absorption layer.

The present inventors then propose, based on the above findings, the following: the sulfur concentration in the VI group element in the depth direction of the CZTS-based light absorption layer is increased from the second electrode layer side towards the first electrode layer side in order to enhance the photoelectric conversion efficiency of the CZTS-based thin-film solar cell.

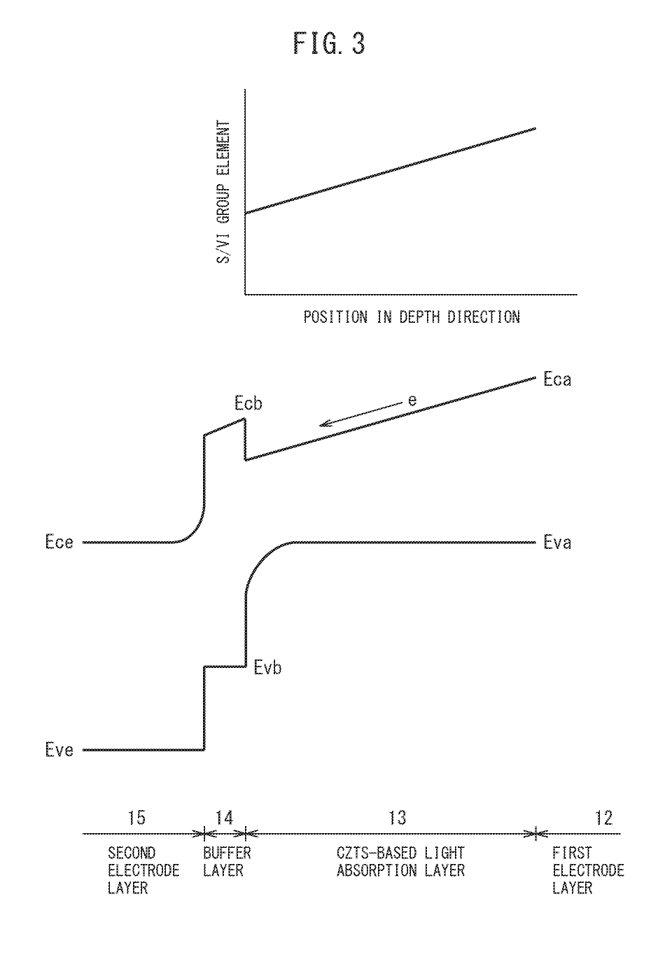

FIG. 3 is a graph illustrating the band structure of the solar cell disclosed in the present specification.

In the graph in FIG. 3, the vertical axis represents the atomic ratio of sulfur to the VI group element in the CZTS-based light absorption layer, and the horizontal axis represents the position in the depth direction of the CZTS-based light absorption layer, from the interface of the buffer layer.

Eca represents the energy level at the lower end of the conduction band of the CZTS-based light absorption layer 13, and Eva represents the energy level at the upper end of the valance band thereof. Ecb represents the energy level at the lower end of the conduction band of the buffer layer 14, and Evb represents the energy level at the upper end of the valance band thereof. Ece represents the energy level at the lower end of the conduction band of the second electrode layer 15, and Eve represents the energy level at the upper end of the valance band thereof. The difference between the energy level at the lower end of the conduction band and the energy level at the upper end of the valance band corresponds to the energy gap.

The CZTS-based light absorption layer 13 can be formed as follows: the sulfur concentration in the VI group element in the depth direction of the CZTS-based light absorption layer 13 is distributed so as to be increased from the second electrode layer 15 side, namely, the buffer layer 14 side towards the first electrode layer 12 side, to result in an increase in the energy level at the lower end of the conduction band of the CZTS-based light absorption layer 13 from the second electrode layer side towards the first electrode layer side.

According to the band structure illustrated in FIG. 3, an electron that absorbs light energy to transit to the lower end of the conduction band is moved to a position where the potential energy is lower, and therefore an electron in the CZTS-based light absorption layer 13 is promoted to be moved to the buffer layer 14 to result in an increase in photoelectric conversion efficiency.

In addition, as illustrated in FIG. 3, the CZTS-based light absorption layer 13 can have a predetermined width of the band gap energy to thereby absorb sunlight in a wider wavelength range, resulting in a further increase in photoelectric conversion efficiency.

With respect to the gradient of the sulfur concentration in the VI group element in the depth direction of the CZTS-based light absorption layer 13, the difference between the minimum value and the maximum value of the atomic ratio of sulfur to the VI group element in the CZTS-based light absorption layer 13 is preferably 0.15 or more from the viewpoint of an enhancement in photoelectric conversion efficiency.

The sulfur concentration in the VI group element herein means the concentration of sulfur contributing to photoelectric conversion of the CZTS-based light absorption layer 13, and the concentration of sulfur not contributing to photoelectric conversion is excluded. While the CZTS-based light absorption layer 13 serving to conduct photoelectric conversion in the solar cell 10 may include a component including sulfur not serving to conduct photoelectric conversion, such sulfur does not contribute to photoelectric conversion and therefore is not considered to involve in the sulfur concentration in the VI group element.

While the sulfur concentration in the depth direction of the CZTS-based light absorption layer 13 is continuously increased from the buffer layer 14 side towards the first electrode layer 12 side in the example illustrated in FIG. 3, the sulfur concentration may be discontinuously increased in a stepwise manner.

In addition, an increase in the sulfur concentration in the VI group element in the depth direction of the CZTS-based light absorption layer 13 from the second electrode layer 15 towards the first electrode layer 12 encompasses a partially constant sulfur concentration in the depth direction. A constant sulfur concentration herein means that the difference between the minimum value and the maximum value of the atomic ratio of sulfur to the VI group element in a predetermined region in the depth direction of the CZTS-based light absorption layer 13 is 0.05 or less. An increase in the sulfur concentration in the VI group element from the second electrode layer 15 side towards the first electrode layer 12 side encompasses a difference between the minimum value and the maximum value of the atomic ratio of sulfur to the VI group element in a predetermined region in the depth direction of the CZTS-based light absorption layer 13, of more than 0.05.

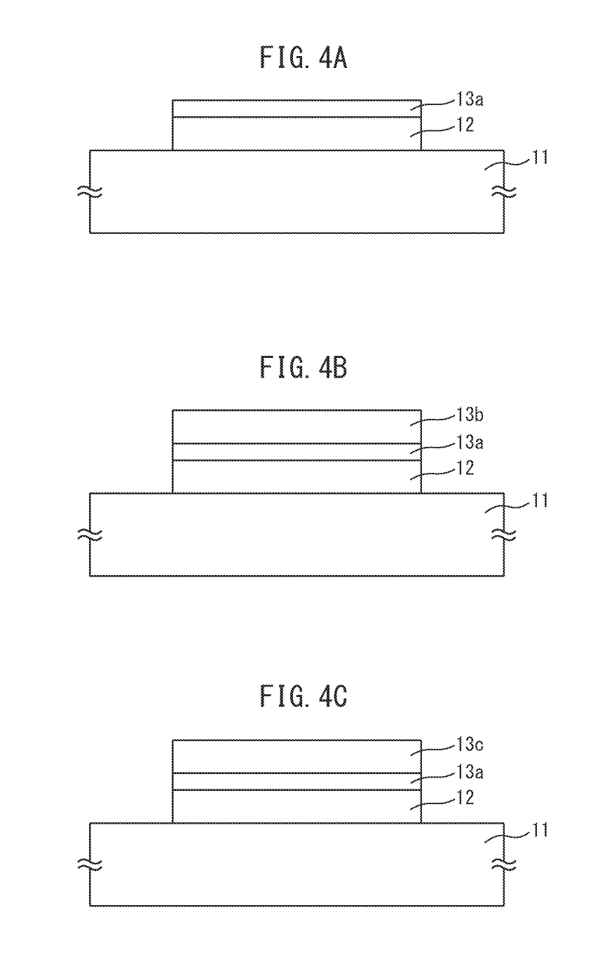

Next, a first embodiment of the method for producing the solar cell disclosed in the present specification is described below with reference to FIG. 4A to FIG. 6.

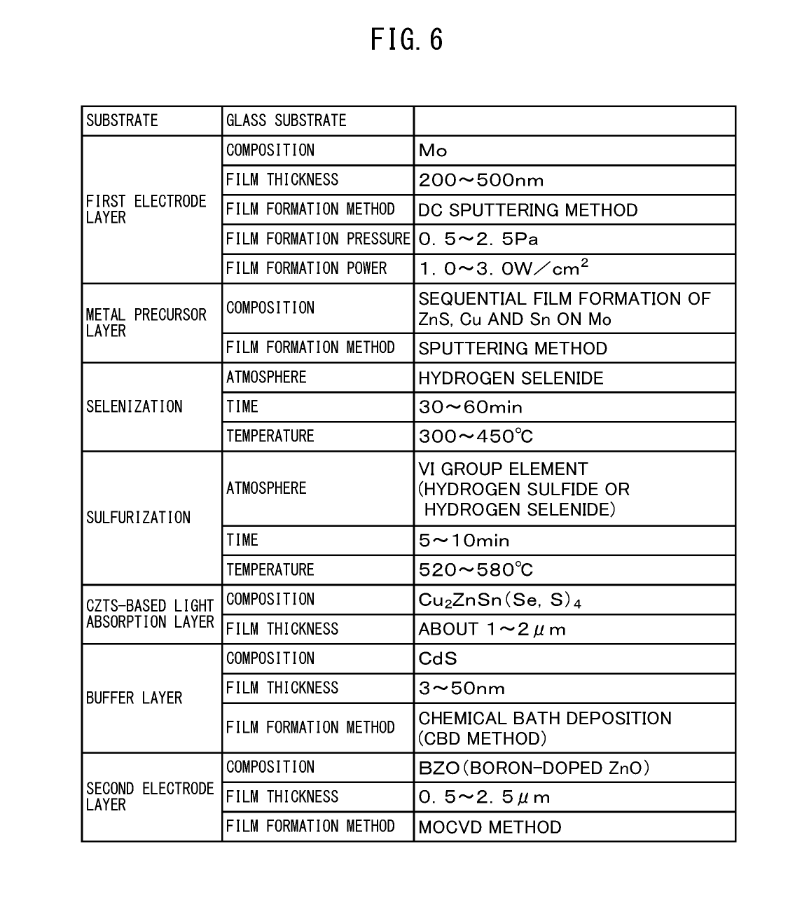

First, as illustrated in FIG. 4A, a first electrode layer 12 is formed on a substrate 11, and a ZnS precursor film 13a is formed on the first electrode layer 12. Specific production conditions used in the present embodiment in the step of FIG. 4A are represented in FIG. 6. The ZnS precursor film 13a may he formed by Zn film formation with a sputtering method or the like followed by a heat treatment (sulfurization) in a sulfur-containing atmosphere.

Next, as illustrated in FIG. 4B, a Cu film and a Sn film are formed on the ZnS precursor film 13a to form a CuSn precursor film 13b. The Cu film or the Sn film may be first formed with respect to the stacking order of the Cu film and the Sn film on the ZnS precursor film 13a. Specific production conditions used in the present embodiment in the step of FIG. 4B are represented in FIG. 6.

Next, as illustrated in FIG. 4C, a compound of the CuSn precursor film 13b and Se is formed, and the CuSn precursor film 13b is subjected to selenization to form a CuSnSe film 13c on the ZnS precursor film 13a. The step of FIG. 4C is preferably performed at such a temperature for such a time that the ZnS precursor film 13a is not decomposed or does not react with Se.

Specific production conditions used in the present embodiment in the step of FIG. 4C are represented in FIG. 6.

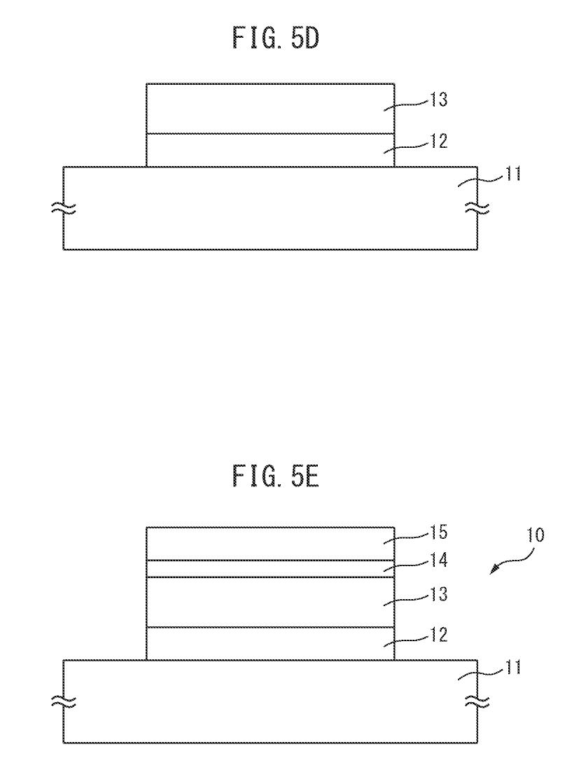

Next, as illustrated in FIG. 5D, the ZnS precursor film 13a and the CuSnSe film 13c are allowed to react under a VI group element atmosphere, to diffuse Zn in the CuSnSe film 13c and also perform sulfurization, thereby forming a CZTS-based light absorption layer 13. The CZTS-based light absorption layer 13 includes a mixed crystal of Cu₂(Zn,Sn)Se₄ and Cu₂(Zn,Sn)S₄. The temperature at which the ZnS precursor film 13a is decomposed to Zn and S is used as the temperature in the step of FIG. 5D. S generated by decomposition of the ZnS precursor film 13a is diffused in the CuSnSe film 13c and moved towards the surface. The time taken for the step of FIG. 5D is determined so that the sulfur concentration in the VI group element in the depth direction of the CZTS-based light absorption layer 13 is distributed increasing from the surface towards the first electrode layer 12. A longer time taken for the step of FIG. 5D is likely to cause the sulfur concentration in the VI group element in the depth direction of the CZTS-based light absorption layer 13 to be constant from the first electrode layer 12 side towards the surface. In addition, a too short time taken for the step of FIG. 5D is likely to cause diffusion of zinc in the CuSnSe film 13c to be insufficient, not resulting in sufficient formation of Cu(Sn, Zn) (S, Se) in the CZTS-based light absorption layer 13. Specific production conditions used in the present embodiment in the step of FIG. 5D are represented in FIG. 6. The reason why the step of FIG. 5D is performed under a VI group element atmosphere is because the VI group element such as S or Se in the CZTS-based light absorption layer 13 is prevented from being diffused and going out of the CZTS-based light absorption layer 13. For example, hydrogen sulfide or hydrogen selenide can be used for the VI group element atmosphere.

The temperature in the step of FIG. 5D is usually higher than the temperature in the step of FIG. 4C, and the time taken for the step of FIG. 5D is usually shorter than the time taken for the step of FIG. 4C. If the ZnS precursor film 13a and the CuSnSe film 13c are allowed to react in the step of FIG. 4C, sulfur may be excessively diffused in the CuSnSe film 13c to make it difficult to control distribution of the sulfur concentration in the step of FIG. 5D.

In the step of FIG. 5D, Zn and S forming the ZnS precursor film 13a are diffused in the CuSnSe film 13c, Cu, Sn and Se forming the CuSnSe film 13c are diffused in the ZnS precursor film 13a, and therefore both the films are integrated to form the CZTS-based light absorption layer 13.

Next, as illustrated in FIG. 5E, an n-type buffer layer 14 is formed on the CZTS-based light absorption layer 13. The n-type buffer layer 14 forms a pn junction with the interface of the p-type CZTS-based light absorption layer 13. Next, a second electrode layer 15 is formed on the buffer layer 14 to provide a solar cell 10 of the present embodiment. Specific production conditions used in the present embodiment in the step of FIG. 5E are represented in FIG. 6.

The first embodiment of the method for producing the solar cell was used to form a solar cell in each of Experimental Example 1 and Experimental Example 2. The evaluation results in Experimental Example 1 and Experimental Example 2 are described later.

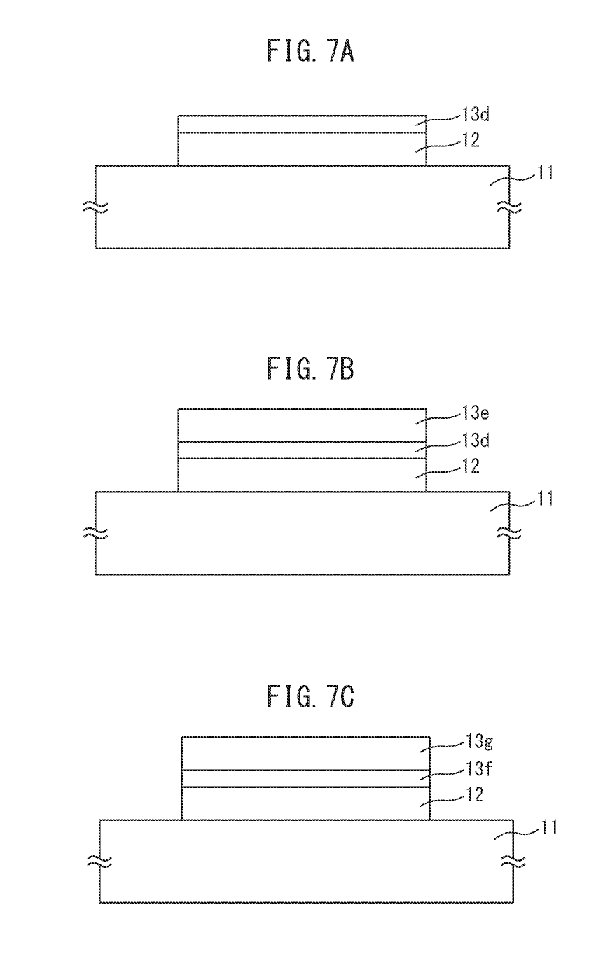

Next, a second embodiment of the method for producing the solar cell disclosed in the present specification is described below with reference to FIG. 7A to FIG. 9.

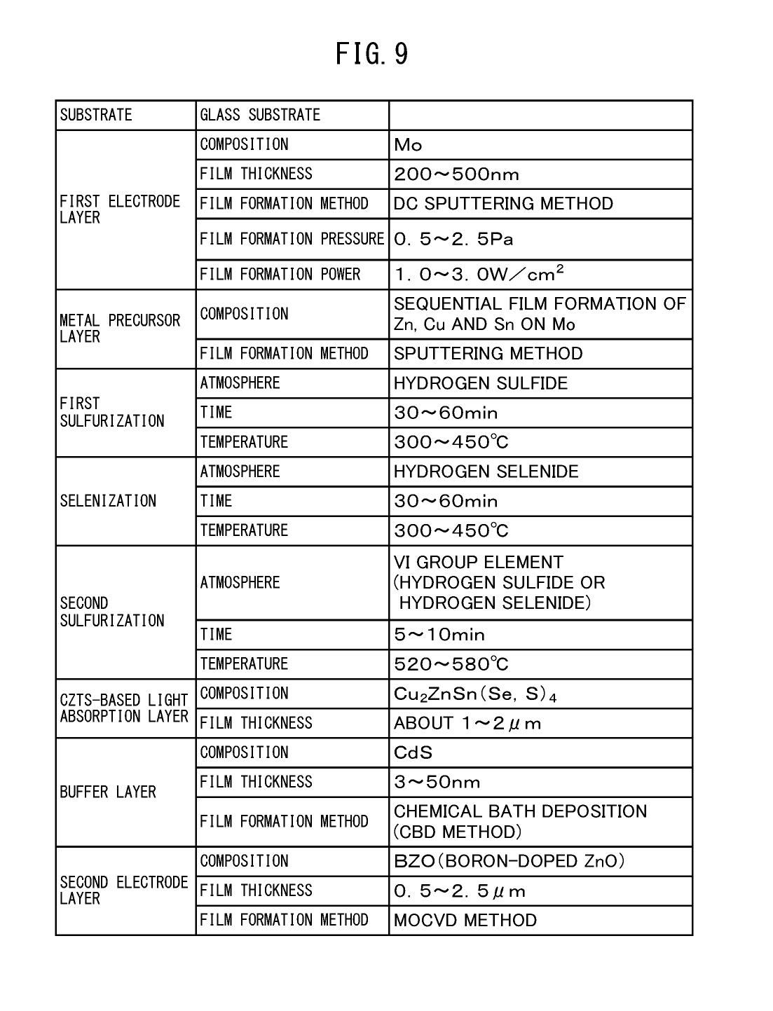

First, as illustrated in FIG. 7A, a first electrode layer 12 is formed on a substrate 11, and a Zn precursor film 13d is formed on the first electrode layer 12. Specific production conditions used in the present embodiment in the step of FIG. 7A are represented in FIG. 9.

Next, as illustrated in FIG. 7B, a Cu film and a Sn film are formed on the Zn precursor film 13d to form a CuSn precursor film 13e. The Cu film or the Sn film may be first formed with respect to the stacking order of the Cu film and the Sn film on the Zn precursor film 13d. Specific production conditions used in the present embodiment in the step of FIG. 7B are represented in FIG. 9.

Next, as illustrated in FIG. 7C, a compound of the Zn precursor film 13d and the CuSn precursor film 13e with S is formed, and the Zn precursor film 13d and the CuSn precursor film 13e are subjected to first sulfurization to form a ZnS precursor film 13f and a CuSnS film 13g. The temperature and the time in the step of FIG. 7C taken therefor are preferably determined so that no reaction occurs between the Zn precursor film 13d and the CuSn precursor film 13e. Specific production conditions used in the present embodiment in the step of FIG. 7C are represented in FIG. 9.

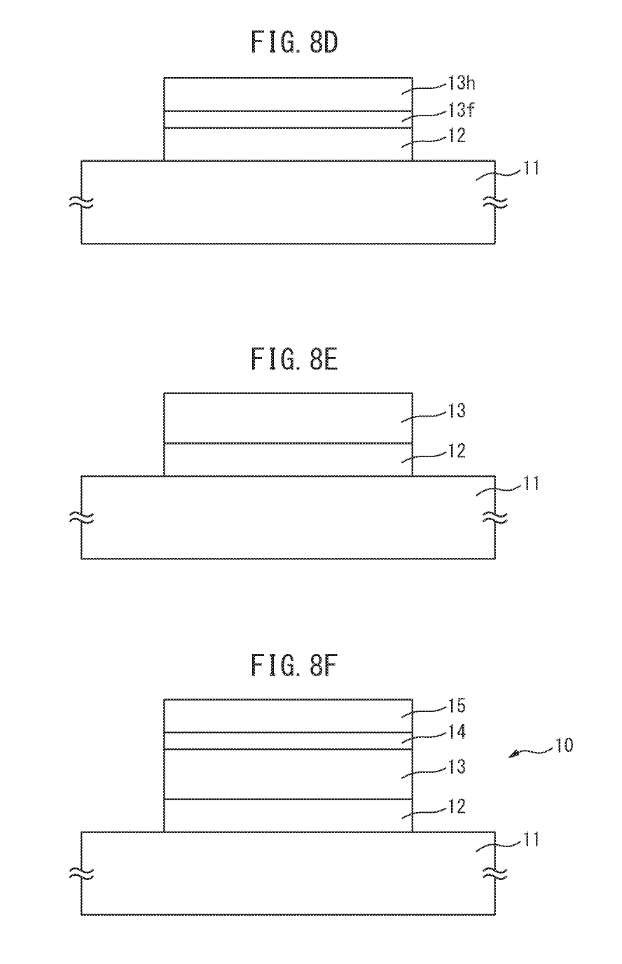

Next, as illustrated in FIG. 8D, the CuSnS film 13g is subjected to selenization in order to partially substitute S in the CuSnS film 13g with Se to form a compound of Cu, Sn and Se, thereby forming a CuSn(Se,S) film 13h on the ZnS precursor film 13f. The step of FIG. 8D is preferably performed at a temperature for a time so that the ZnS precursor film 13f is not decomposed and does not react with Se. Specific production conditions used in the present embodiment in the step of FIG. 8D are represented in FIG. 9.

Next, as illustrated in FIG. 8E, the ZnS precursor film 13f and the CuSn(Se,S) film 13h are allowed to react under a VI group element atmosphere, to diffuse Zn in the CuSn(Se,S) film 13h and also perform second sulfurization, thereby forming a CZTS-based light absorption layer 13. The CZTS-based light absorption layer 13 includes a mixed crystal of Cu₂(Zn,Sn)Se₄ and Cu₂(Zn,Sn)S₄. The temperature where the ZnS precursor film 13f is decomposed to Zn and S is used as the temperature in the step of FIG. 8E. In addition, the time taken for the step of forming the ZnS precursor film 13f is determined so that the sulfur concentration the VI group element in the depth direction of the CZTS-based light absorption layer 13 is increased from the surface towards the first electrode layer 12 side. An object of the step of FIG. 8E is the same as that of the step of FIG. 5D, and therefore the description of sulfurization in FIG. 5D is appropriately applied to the description of the step of FIG. 8E. Specific production conditions used in the present embodiment in the step of FIG. 8E are represented in FIG. 9.

In the step of FIG. 8E, Zn and S forming the ZnS precursor film 13f are diffused in the CuSn(Se,S) film 13h, Cu, Sn, Se and S forming the CuSn(Se,S) film 13h are diffused in the ZnS precursor film 13f, and therefore both the films are integrated to form the CZTS-based light absorption layer 13.

Next, as illustrated in FIG. 8F, an n-type buffer layer 14 is formed on the CZTS-based light absorption layer 13. The n-type buffer layer 14 forms a pn junction with the interface of the p-type CZTS-based light absorption layer 13. Next, a second electrode layer 15 is formed on the buffer layer 14 to provide a solar cell 10 of the present embodiment. Specific production conditions used in the present embodiment in the step of FIG. 8F are represented in FIG. 9.

The solar cell disclosed in the present specification may be formed by any method other than the above embodiments. For example, the solar cell may be formed with a vapor deposition method. Specifically, when Cu, Sn, Zn, Se and S are vapor-deposited on the first electrode layer 12 with a simultaneous vapor deposition method, the CZTS-based light absorption layer 13 may be formed while the S/Se ratio is reduced in a stepwise or continuous manner. Even such a method can be used to form the CZTS-based light absorption layer 13 so that the sulfur concentration in the VI group element in the depth direction of the CZTS-based light absorption layer 13 is increased from the surface towards the first electrode layer 12 side.

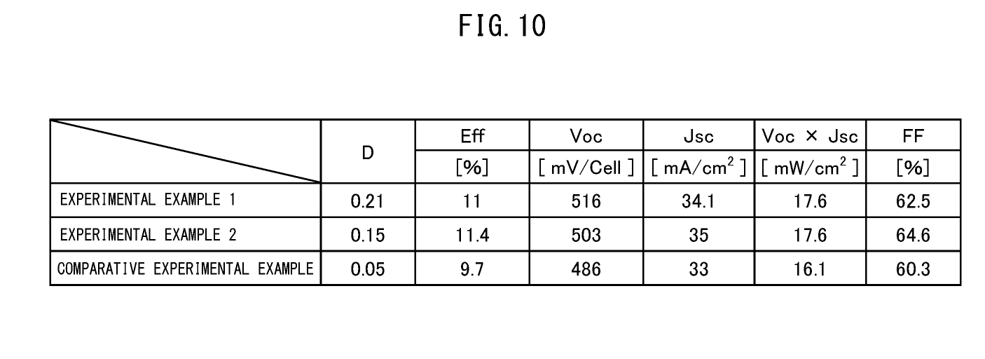

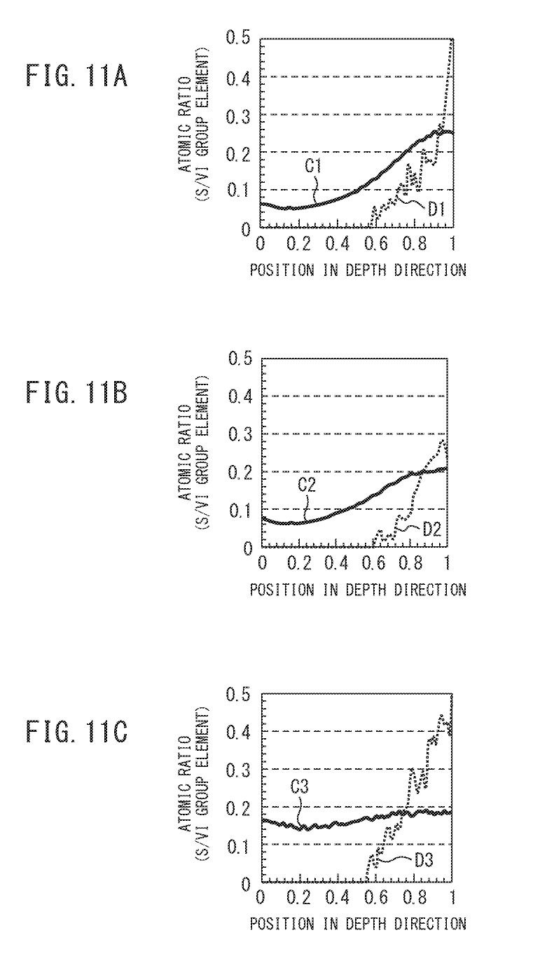

Next, the evaluation results of the solar cell in each of Experimental Example 1 and Experimental Example 2, formed with the first embodiment of the method for producing the solar cell, are described below with reference to FIG. 10 and FIG. 11.

FIG. 10 is a diagram describing the evaluation results in Experimental Example 1 and Experimental Example 2, and Comparative Experimental Example disclosed in the present specification.

The distribution of the sulfur concentration in the VI group element in the depth direction of the CZTS-based light absorption layer 13 is changed among Experimental Example 1 and Experimental Example 2, and Comparative Experimental Example, due to different temperature and time conditions in the step of FIG. 5D.

FIG. 10 illustrates the evaluation results of the photoelectric conversion efficiency Eff, the open voltage Voc, the current density Jsc, the product Voc×Jsc of the open voltage and the current density, and the fill factor FF of the solar cell of each of Experimental Example 1 and Experimental Example 2, and Comparative Experimental Example. In addition, FIG. 10 illustrates the difference D between the minimum value and the maximum value of the atomic ratio of sulfur to the VI group element in the depth direction of the CZTS-based light absorption layer of the solar cell of each of Experimental Example 1 and Experimental Example 2, and Comparative Experimental Example.

The photoelectric conversion efficiency Eff in each of Experimental Example 1 and Experimental Example 2 exhibits a value enhanced by 10% or more as compared with that in Comparative Experimental Example. In addition, it is seen that other characteristics in each of Experimental Example 1 and Experimental Example 2 are also enhanced as compared with those in Comparative Experimental Example.

The difference D is described below with reference to FIG. 11A to FIG. 11C.

FIG. 11A is a graph illustrating the distribution in the depth direction of the atomic ratio of sulfur to the VI group element in Experimental Example 1 disclosed in the present specification. FIG. 11B is a graph illustrating the distribution in the depth direction of the atomic ratio of sulfur to the VI group element in Experimental Example 2 disclosed in the present specification. FIG. 11C is a graph illustrating the distribution in the depth direction of the atomic ratio of sulfur to the VI group element in Comparative Experimental Example disclosed in the present specification.

FIG. 11A to FIG. 11C illustrate the results of measurement of the sulfur concentration (atom concentration) with SIMS (secondary ion mass spectroscopy). In FIG. 11, the vertical axis represents the atomic ratio of sulfur to the VI group element in the CZTS-based light absorption layer, and the horizontal axis represents the position in the depth direction of the CZTS-based light absorption layer, from the interface with the buffer layer, in arbitrary unit.

FIG. 11A illustrates the measurement results in Experimental Example 1, FIG. 11B illustrates the measurement results in Experimental Example 2, and FIG. 11C illustrates the measurement results in Comparative Experimental Example.

The difference D between the minimum value and the maximum value of the atomic ratio of sulfur to the VI group element in the depth direction of the CZTS-based light absorption layer was calculated based on the measurement results represented in FIG. 11. The difference D is an indicator of the amount of increase in distribution of the sulfur concentration in the VI group element in the CZTS-based light absorption layer.

Curve C1 in FIG. 11A represents the atomic ratio of sulfur to the VI group element in the CZTS-based light absorption layer. Similarly, curves C2 and C3 in FIG. 11B and FIG. 11C, respectively, represent the atomic ratio of sulfur to the VI group element contributing to photoelectric conversion of the CZTS-based light absorption layer. The number of sulfur atoms means the number of sulfur atoms contributing to photoelectric conversion of the CZTS-based light absorption layer. While the CZTS-based light absorption layer also includes sulfur based on ZnS, ZnS does not contribute to photoelectric conversion of the CZTS-based light absorption layer and therefore does not involve in the sulfur concentration in the VI group element.

Curve D1 in FIG. 11A plots the number of sulfur atoms due to ZnS for reference. The number of sulfur atoms due to ZnS is represented by an arbitrary unit. Similarly, curves D2 and D3 in FIG. 11B and FIG. 11C, respectively, plot the number of sulfur atoms due to ZnS.

In the following is described about determination of the sulfur concentration in the VI group element contributing to photoelectric conversion of the CZTS-based light absorption layer, from the measurement results with SIMS.

First, the number of Zn atoms, the number of Sn atoms, the number of Se atoms and the number of S atoms in the CZTS-based light absorption layer are measured with SIMS.

While the atomic ratio of Zn in the II group element to Sn in the IV group element is basically constant 1:1 in consideration that the I group element, the II group element, the IV group element and the VI group element contributing to photoelectric conversion of the CZTS-based light absorption layer in each of Experimental Example 1 and Experimental Example 2, and Comparative Experimental Example are based on the compositional ratio of the I₂-(II-IV)-VI₄ group compound, the Zn/Sn ratio may be 1 to 1.2 for an enhancement in performance, to thereby provide a CZTS-based light absorption layer including excessive Zn. In Experimental Examples and Comparative Experimental Example in the present embodiment, the Zn/Sn ratio is about 1.1. In addition, the atomic ratio of Zn to S forming ZnS is considered to be 1:1.

The atomic ratio (Zn/Sn ratio) of Zn in the II group element to Sn in the IV group element contributing to photoelectric conversion of the CZTS-based light absorption layer is 1.1 and a constant compositional ratio is exhibited in the film thickness direction, and therefore the number of Zn atoms contributing to photoelectric conversion can be calculated from the number of Sn atoms measured. The number of Zn atoms contributing to photoelectric conversion, calculated from the number of Zn atoms measured, is subtracted to provide the number of Zn atoms due to ZnS. In the present embodiment, while the Zn/Sn ratio is 1.1, the calculation procedure can also be applied to a CZTS-based light absorption layer where such a ratio is in the range from 1.0 to 1.3. In this case, the Zn/Sn ratio at a location contributing to photoelectric conversion (for example, the Zn/Sn ratio in a certain area from the surface of the light absorption layer) is determined from the measurement value with SIMS, and can be utilized to thereby calculate the number of Zn atoms contributing to photoelectric conversion from the number of Sn atoms.

The number of Zn atoms due to ZnS is the same as the number of S atoms due to ZnS, and therefore the number of Zn atoms due to ZnS is subtracted from the number of S atoms measured, to provide the number of S atoms contributing to photoelectric conversion of the CZTS-based light absorption layer.

Thus, the atomic ratio of sulfur to the VI group element, and the number of S atoms due to ZnS, illustrated in FIG. 11, are calculated.

As illustrated in FIG. 11A, the atomic ratio of sulfur to the VI group element contributing to photoelectric conversion of the CZTS-based light absorption layer is increased from the buffer layer side towards the first electrode layer side, in Experimental Example 1. In other words, the sulfur concentration in the VI group element in the depth direction of the CZTS-based light absorption layer is increased from the buffer layer side towards the first electrode layer side. While the atomic ratio appears to be decreased in a portion closer to the buffer layer of the CZTS-based light absorption layer, the difference between the minimum value and the maximum value of the atomic ratio of sulfur to the VI group element in such a portion is 0.05 or less, and therefore the sulfur concentration is regarded as being constant.

As illustrated in FIG. 11B, the atomic ratio of sulfur to the VI group element contributing to photoelectric conversion of the CZTS-based light absorption layer is increased from the buffer layer side towards the first electrode layer side, also in Experimental Example 2.

On the other hand, as illustrated in FIG. 11C, the difference D between the minimum value and the maximum value of the atomic ratio of sulfur to the VI group element in the depth direction of the CZTS-based light absorption layer is 0.05 or less in Comparative Experimental Example, and therefore the sulfur concentration is regarded as being constant over the entire CZTS-based light absorption layer. In other words, the sulfur concentration in the VI group element in the depth direction of the CZTS-based light absorption layer is constant from the buffer layer side towards the first electrode layer side, in Comparative Experimental Example.

As illustrated in FIG. 11A and FIG. 11B, the minimum value of the atomic ratio is less than 0.1, the maximum value thereof is more than 0.2, and the difference D between the minimum value and the maximum value of the atomic ratio of sulfur to the VI group element in the depth direction of the CZTS-based light absorption layer represents 0.15 or more, in both of Experimental Example 1 and Experimental Example 2.

On the other hand, as illustrated in FIG. 11C, the difference D between the minimum value and the maximum value of the atomic ratio of sulfur to the VI group element in the depth direction of the CZTS-based light absorption layer is 0.05 or less in Comparative Experimental Example.

As illustrated in FIG. 11A and FIG. 11B, S due to ZnS is distributed in a portion closer to the first electrode layer of the CZTS-based light absorption layer. It is thus presumed that ZnS is distributed in a portion closer to the first electrode layer of the CZTS-based light absorption layer. The reason is considered because ZnS remains while the ZnS film formed in the step of FIG. 4A of the first embodiment of the method for producing the solar cell is not decomposed.

In the present invention, the solar cell and the method for producing the solar cell of the embodiments can be appropriately modified without departing from the spirit of the present invention. In addition, components in one embodiment can be appropriately applied to other embodiments.

For example, the CZTS-based light absorption layer includes S and Se as the VI group element in the above embodiments, but may include other VI group element.

### REFERENCE SIGNS LIST

10 solar cell
11 substrate
12 first electrode layer
13 CZTS-based light absorption layer
13a ZnS precursor film
13b CuSn precursor film
13c CuSnSe film
13d Zn precursor film
13e CuSn precursor film
13f ZnS precursor film
13g CuSnS film
13h CuSn(Se,S) film
14 buffer layer
15 second electrode layer

1. A solar cell comprising:
a substrate,
a first electrode layer disposed on the substrate,
a p-type CZTS-based light absorption layer disposed on the first electrode layer and having copper, zinc and tin, and a VI group element comprising sulfur and selenium, and
an n-type second electrode layer disposed on the CZTS-based light absorption layer, wherein
the sulfur concentration in the VI group element in the depth direction of the CZTS-based light absorption layer is increased from the second electrode layer side towards the first electrode layer side.

2. The solar cell according to claim 1, wherein the difference between the minimum value and the maximum value of the atomic ratio of sulfur to the VI group element in the CZTS -based light absorption layer is 0.15 or more.

3. The solar cell according to claim 1, wherein the minimum value of the atomic ratio of sulfur to the VI group element in the depth direction of the CZTS-based light absorption layer is less than 0.1.

4. The solar cell according to claim 1, wherein the maximum value of the atomic ratio of sulfur to the VI group element in the depth direction of the CZTS-based light absorption layer is more than 0.2.

5. The solar cell according to claim 1, wherein an n-type buffer layer is disposed between the CZTS-based light absorption layer and the second electrode layer.
